(19) United States
(12) Patent Application Publication
(10) Pub. No.: US 2025/0031504 A1
(43) Pub. Date: Jan. 23, 2025

(54) METHOD OF MANUFACTURING DISPLAY DEVICE AND DISPLAY DEVICE

(71) Applicant: Samsung Display Co., LTD., Yongin-si (KR)

(72) Inventor: Jeong Moon LEE, Yongin-si (KR)

(21) Appl. No.: 18/412,347

(22) Filed: Jan. 12, 2024

(30) Foreign Application Priority Data
Jul. 20, 2023 (KR) 10-2023-0094813

(51) Int. Cl. H01L 33/62; H01L 25/075; H01L 25/16; H01L 33/42

(52) U.S. Cl. CPC H01L 33/62; H01L 25/0753; H01L 25/167; H01L 33/42; H01L 2933/0016

(57) ABSTRACT

A method of manufacturing a display device includes: providing a carrier module including a carrier wafer and light emitting elements; disposing the carrier module on a transparent electrode assembly; inspecting the light emitting elements; and transferring the light emitting elements onto a pixel circuit layer after the inspecting the light emitting elements.

This application claims priority to Korean patent application No. 10-2023-0094813, filed on Jul. 20, 2023, and all the benefits accruing therefrom under 35 U.S.C. § 119, the content of which in its entirety is herein incorporated by reference.

### BACKGROUND

### 1. Field

The disclosure generally relates to a method of manufacturing a display device and a display device.

### 2. Description of the Related Art

Recently, as interest in information displays is increased, research and development of display devices have been continuously conducted.

A display device may include a light emitting element. In a process of manufacturing the display device, a process of manufacturing a light emitting element and transferring the light emitting element to a backplane layer or the like of the display device may be performed.

In order to ensure the uniformity of quality of the display device, an inspection process on the light emitting element may be performed during the process of manufacturing the display device.

### SUMMARY

In a process of manufacturing a display device, an electrical signal for light emission is desired to be supplied to a light emitting element to perform an inspection process on the light emitting element. However, it may be difficult for the inspection process to be performed before the light emitting element is transferred to a backplane layer.

Embodiments provide a method of manufacturing a display device and a display device, in which a failure rate of light emitting elements is decreased, so that process efficiency can be improved.

Embodiments also provide a method of manufacturing a display device and a display device, in which an inspection process on a light emitting element can be appropriately performed.

In accordance with an embodiment of the present disclosure, a method of manufacturing a display device includes: providing a carrier module including a carrier wafer and light emitting elements; disposing the carrier module on a transparent electrode assembly; inspecting the light emitting elements; and transferring the light emitting elements onto a pixel-circuit layer after the inspecting the light emitting elements.

In an embodiment, the providing the carrier module may include: growing semiconductor layers on a growth substrate; providing the light emitting elements by etching the semiconductor layers, where the light emitting elements may be spaced apart from each other and each of the light emitting elements may include a first semiconductor layer, a second semiconductor layer, and an active layer between the first semiconductor layer and the second semiconductor layer; coupling the light emitting elements and the carrier wafer to each other; and separating the light emitting elements and the growth substrate from each other.

In an embodiment, the carrier wafer may include silicon (Si).

In an embodiment, the carrier wafer may have electrical conductivity.

In an embodiment, the providing the carrier module may include: providing a bonding electrode in a pattern shape on the carrier wafer; and providing a reflective electrode in a pattern shape on the semiconductor layers.

In an embodiment, the transparent electrode assembly may include a glass substrate and electrodes disposed on the glass substrate. In such an embodiment, the electrodes may include: first electrodes extending in a first extending direction; and second electrodes extending in a second extending direction different from the first extending direction, where the second electrodes may be integrally formed with the first electrodes as a single unitary and indivisible part.

In an embodiment, the first electrodes and the second electrodes may intersect each other in intersection areas. In such an embodiment, The intersection areas may be arranged in a matrix form in which a row direction may be the first extending direction and a column direction may be the second extending direction.

In an embodiment, the glass substrate may include a glass material, and the electrodes may include a transparent electrode material.

In an embodiment, the inspecting the light emitting elements may include supplying power to the electrodes such that the power is supplied to the light emitting elements.

In an embodiment, the supplying the power to the electrodes may include supplying, by a power apply unit, the power to pads connected to the electrodes through a power supply pin.

In an embodiment, the inspecting the light emitting elements may include allowing the light emitting elements to emit light.

In an embodiment, the inspecting the light emitting elements may include acquiring visual information on the light emitting elements. In such an embodiment, the visual information may include mapping information of the light emitting elements on the transparent electrode assembly and information on whether the light emitting elements emit light for each of positions at which the light emitting elements are disposed, respectively.

In an embodiment, the mapping information may be predetermined based on the matrix from defined by the intersection areas.

In an embodiment, the method may further include repairing at least one of the light emitting elements. In such an embodiment, the repairing may be performed after the inspecting the light emitting elements, and be performed before the transferring the light emitting elements onto the pixel-circuit layer.

In an embodiment, the inspecting the light emitting elements may include: determining the at least one of the light emitting elements as an abnormal light emitting element which abnormally emits light; and determining others of the light emitting elements as a normal light emitting element which normally emits light. In such an embodiment, the repairing may include individually repairing the at least one of the light emitting elements determined as the abnormal light emitting elements.

In an embodiment, the inspecting the light emitting elements may include: determining the at least one of the light emitting elements as an abnormal light emitting element which abnormally emits light; and determining others of the light emitting elements as a normal light emitting element which normally emits light. In such an embodiment, the repairing may include repairing the at least one of the light emitting elements determined as the abnormal light emitting element with respect to an area in which the abnormal light emitting element is included at a predetermined rate or higher.

In an embodiment, the transferring the light emitting elements onto the pixel-circuit layer may include removing the carrier wafer in the carrier module and disposing the light emitting elements on the pixel-circuit layer.

In accordance with an embodiment of the present disclosure, a display device is manufactured by the method.

In an embodiment, the pixel-circuit layer may include a pixel circuit, and the light emitting elements may be electrically connected to the pixel circuit.

In an embodiment, each of the light emitting elements may be a micro light emitting diode (LED).

### BRIEF DESCRIPTION OF THE DRAWINGS

The above and other features of the invention will become more apparent by describing in further detail embodiments thereof with reference to the accompanying drawings, in which:“ ”

FIG. 1 is a schematic plan view illustrating a display device in accordance with an embodiment of the present disclosure;

FIG. 2 is a schematic sectional view illustrating a display device in accordance with an embodiment of the present disclosure;

FIG. 3 is a flowchart illustrating a method of manufacturing a display device in accordance with an embodiment of the present disclosure;

FIGS. 4 to 9 are schematic process views illustrating a process of providing a carrier module in accordance with an embodiment of the present disclosure;

FIGS. 10 and 11 are process views illustrating a process of disposing the carrier module on a transparent electrode assembly in accordance with an embodiment of the present disclosure;

FIGS. 12 to 15 are process views illustrating a process of inspecting a light emitting element in accordance with an embodiment of the present disclosure; and

FIGS. 16 and 17 are schematic views illustrating a process of transferring the light emitting element in accordance with an embodiment of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof“ ” “ ” “ ” “ ” “ ” “ ” “ ” “ ” “ ” “ ”.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The disclosure generally relates to a method of manufacturing a display device and a display device. Hereinafter, a method of manufacturing a display device and a display device in accordance with an embodiment of the disclosure will be described with reference to the accompanying drawings.

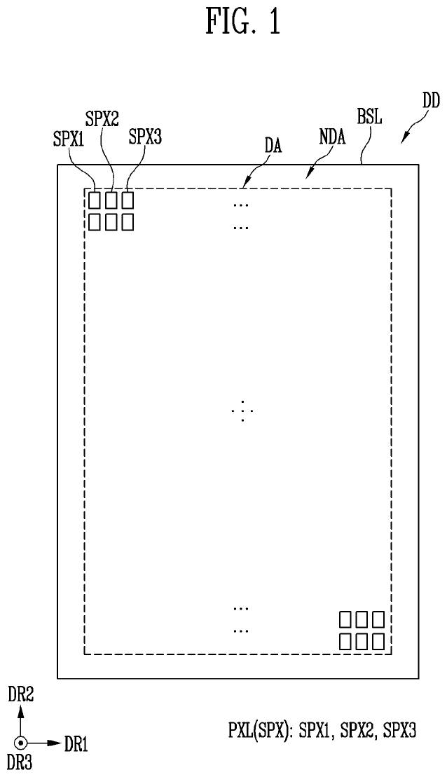

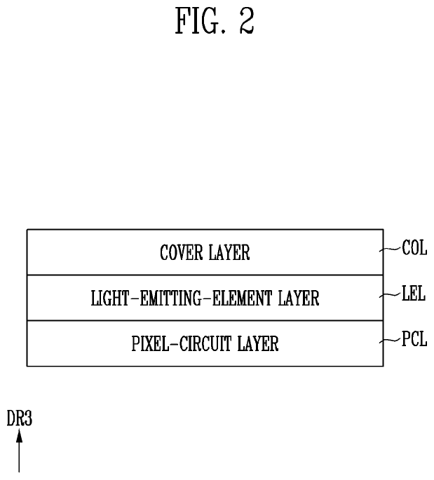

A display device DD in accordance with an embodiment of the disclosure will be described with reference to FIGS. 1 and 2.

FIG. 1 is a schematic plan view illustrating a display device in accordance with an embodiment of the present disclosure.

Referring to FIG. 1, an embodiment of the display device DD may include a base layer BSL and pixels PXL arranged on the base layer BSL. Although not shown in the drawing, the display device DD may further include a driving circuit part (e.g., a scan driver and a data driver) for driving the pixels PXL, lines, and pads.

The display device DD (or the base layer BSL) may include a display area DA and a non-display area NDA. In such an embodiment, the display area DA and the non-display area NDA may be defined in the display device DD or defined on the base layer BSL. The non-display area NDA may mean an area except the display area DA. The non-display area NDA may surround at least a portion of the display area DA.

The base layer BSL may form a base surface of the display device DD. The base layer BSL may be a rigid or flexible substrate or film. In an embodiment, for example, the base layer BSL may be a rigid substrate including or made of glass or tempered glass, a flexible substrate (or thin film) made of a plastic or metal material, or at least one insulating layer. The material and/or property of the base layer BSL is not particularly limited. In an embodiment, the base layer BSL may be substantially transparent. The term “substantially transparent” may mean that light can be transmitted with a predetermined transmittance or more. In another embodiment, the base layer BSL may be translucent or opaque. Also, the base layer BSL may include a reflective material in some embodiments.

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

In accordance with an embodiment, the pixels PXL (or sub-pixels SPX) may be arranged according to a stripe arrangement structure, a PENTILE™ arrangement structure, or the like. However, the disclosure is not limited thereto, and various embodiments may be applied in the present disclosure.

In accordance with an embodiment, the pixel PXL (or the sub-pixels SPX) may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. At least one first sub-pixel SPXL1, at least one second sub-pixel SPXL2, and at least one third sub-pixel SPXL3 may constitute one pixel unit configured to emit lights of various colors.

In an embodiment, each of the first sub-pixel SPXL1, the second sub-pixel SPXL2, and the third sub-pixel SPXL3 may emit light of one color. In an embodiment, for example, the first sub-pixel SPXL1 may be a red pixel that emits light of red (e.g., a first color), the second sub-pixel SPXL2 may be a green pixel that emits light of green (e.g., a second color), and the third sub-pixel SPXL3 may be a blue pixel that emits light of blue (e.g., a third color). In accordance with an embodiment, a number of second sub-pixels SPXL2 may be greater than a number of first sub-pixels SPXL1 and a number of third sub-pixels SPXL3. However, the color, kind, and/or number of first, second, and third sub-pixels SPXL1, SPXL2, and SPXL3 constituting each pixel unit are not limited to a specific example.

FIG. 2 is a schematic sectional view illustrating a display device in accordance with an embodiment of the present disclosure.

Referring to FIG. 2, an embodiment of the display device DD may include a pixel-circuit layer PCL (e.g., a backplane layer), a light-emitting-element layer LEL, and a cover layer COL.

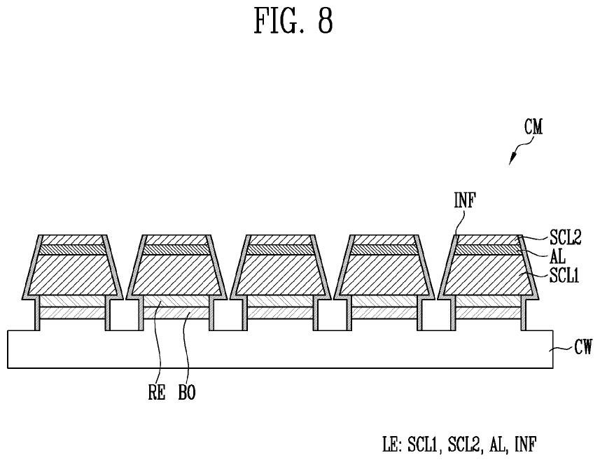

The pixel-circuit layer PCL may be a layer including a pixel circuit for driving a pixel PXL formed or defined by the light-emitting-element layer LEL (or a light emitting element LE (see FIG. 8) included in the light-emitting-element layer LEL). The pixel-circuit layer PCL may include a base layer BSL, conductive layers constituting or for forming pixel circuits, and insulating layers disposed on the conductive layers.

The light-emitting-element layer LEL may be disposed on the pixel-circuit layer PCL. In some embodiments, the light-emitting-element layer LEL may include the light emitting element LE. In some embodiments, the light emitting element LE may include an inorganic light emitting element including an inorganic material. However, the disclosure is not necessarily limited thereto.

In some embodiments, the light emitting element LE may have nano to micro scales. In an embodiment, for example, the light emitting element LE may be a micro light emitting diode (LED). However, the disclosure is not limited thereto.

The cover layer COL may be disposed on the light-emitting-element layer LEL. The cover layer COL may allow light emitted from the light-emitting-element layer LEL to be transmitted therethrough. The cover layer COL may include a window. The cover layer COL may include a structure (e.g., a film or layer stacked structure) for preventing external light reflection. However, the disclosure is not limited thereto.

An inspection process for determining whether light emitting elements LE included in the display device DD normally operate may be thoroughly performed during a manufacturing process, so that a failure rate of the light emitting elements LE can be decreased. Accordingly, a process yield can be substantially improved.

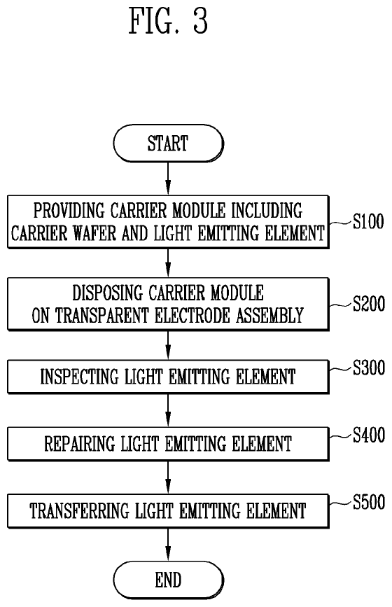

Hereinafter, an embodiment of a method of manufacturing a display device DD, which includes an inspection process of the display device DD, will be described with reference to the drawings from FIG. 3.

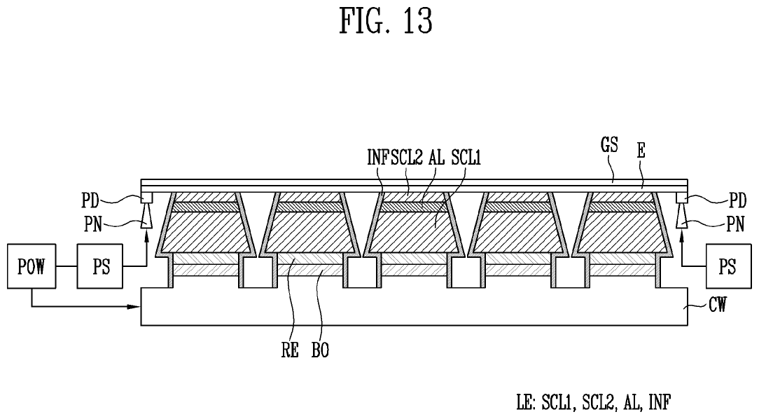

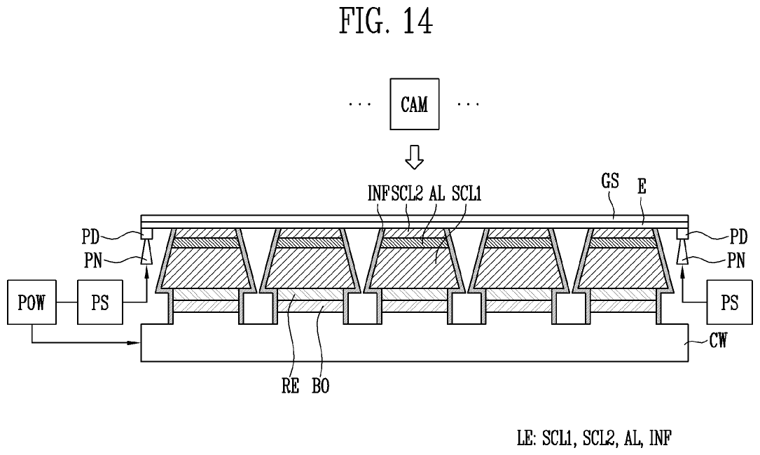

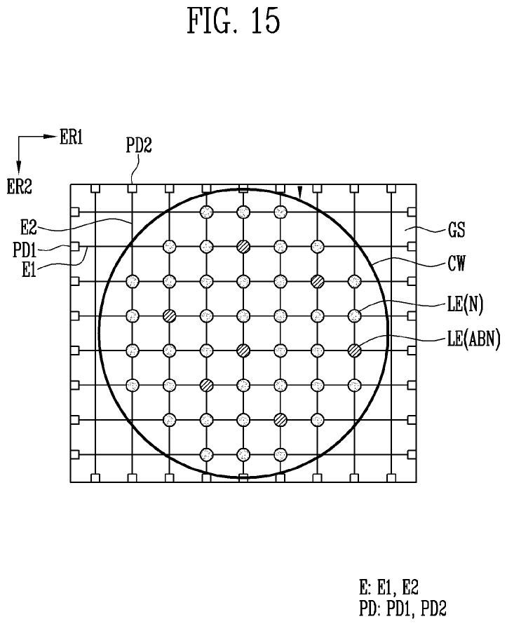

FIGS. 3 to 16 are views illustrating a method of manufacturing a display device DD in accordance with an embodiment of the present disclosure.

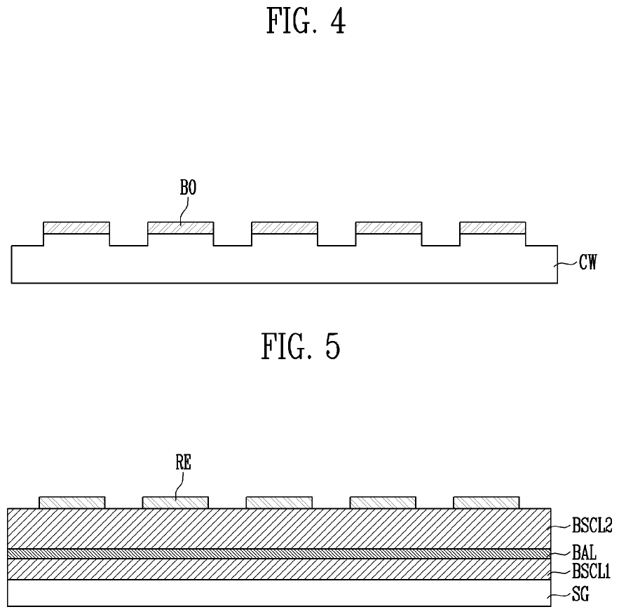

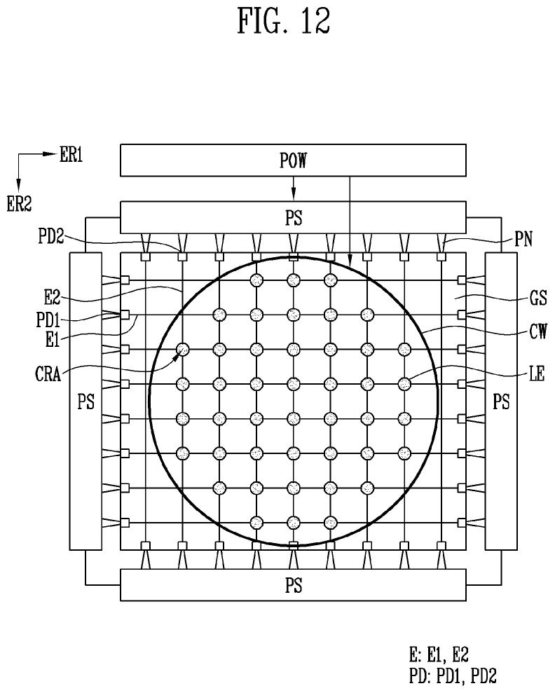

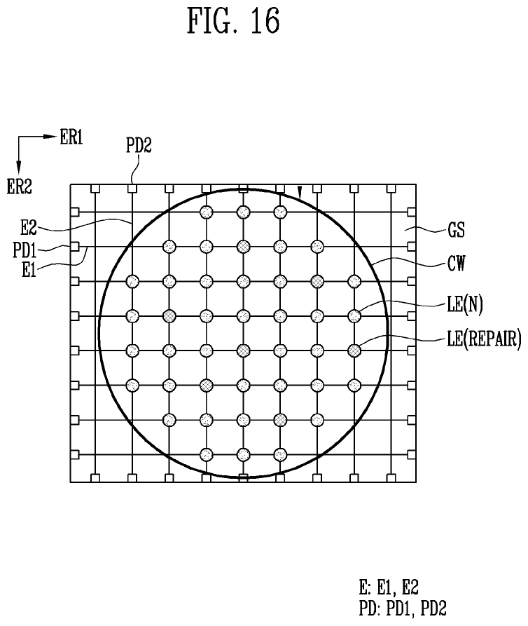

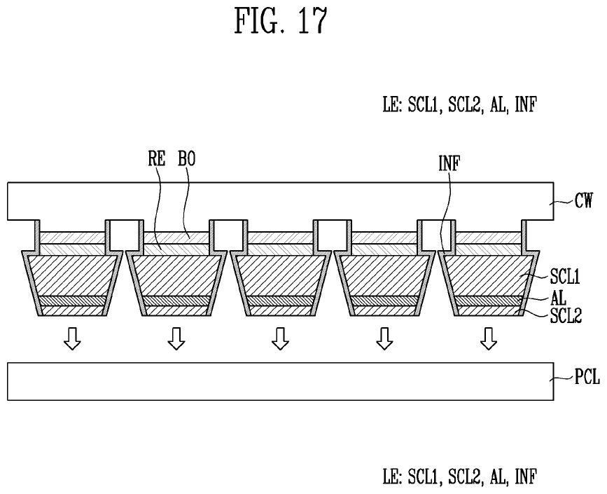

FIG. 3 is a flowchart illustrating a method of manufacturing a display device in accordance with an embodiment of the present disclosure. FIGS. 4 to 9 are schematic process views illustrating a process of providing a carrier module in accordance with an embodiment of the present disclosure. FIGS. and 11 are process views illustrating a process of disposing the carrier module on a transparent electrode assembly in accordance with an embodiment of the present disclosure. FIGS. 12 to 15 are process views illustrating a process of inspecting a light emitting element in accordance with an embodiment of the present disclosure. FIGS. 16 and 17 are schematic views illustrating a process of transferring the light emitting element in accordance with an embodiment of the present disclosure.

Referring to FIG. 3, the method of manufacturing the display device DD in accordance with an embodiment of the disclosure may include a process S100 of providing a carrier module including a carrier wafer and a light emitting element, a process S200 of disposing the carrier module on a transparent electrode assembly, a process S300 of inspecting the light emitting element, step S400 of repairing the light emitting element, and a process S500 of transferring the light emitting element.

Referring to FIGS. 3 to 9, in the process S100 of providing the carrier module including the carrier wafer and the light emitting element, a light emitting element LE may be prepared, and a carrier module CM may be manufactured as the light emitting element LE is coupled to a carrier wafer CW.

Referring to FIG. 4, in the process S100 of providing the carrier module including the carrier wafer and the light emitting element, bonding electrodes BO may be patterned on the carrier wafer CW.

The carrier wafer CW may be a moving member temporarily attached to transfer the light emitting element LE. The carrier wafer CW may include various materials. In some embodiments, the carrier wafer CR may include silicon (Si). The material of the carrier wafer CW in accordance with an embodiment of the disclosure is not particularly limited.

The carrier wafer CW in accordance with an embodiment of the disclosure may serve as a path for supplying an electrical signal to the light emitting element LE to perform an inspection process of the light emitting element LE. In an embodiment, the carrier wafer CW may have electrical conductivity to allow the electrical signal to be supplied to the light emitting element LE therethrough.

The bonding electrodes BO may be provided to couple the light emitting element LE and the carrier wafer CW to each other in a subsequent process. The bonding electrodes BO may be patterned (or formed by a patterning process) in a predetermined reference shape. In an embodiment, for example, the bonding electrodes BO may be disposed to correspond to positions of respective light emitting elements LE which are individually divided or separated from each other.

Referring to FIG. 5, in the process S100 of providing the carrier module including the carrier wafer and the light emitting element, semiconductor materials may be sequentially formed on a growth substrate SG, and reflective electrodes RE may be provided thereon in a pattern shape.

The growth substrate SG may be a base plate for growing a target material. In an embodiment, for example, the growth substrate SG may be a wafer for epitaxial growth of one material. In an embodiment, the growth substrate SG is a sapphire substrate, and may include aluminum oxide (AlOₓ). However, the disclosure is not limited thereto.

In this process, a first base semiconductor layer BSCL1, a base active layer BAL, and a second base semiconductor layer BSCL2 may be sequentially formed (e.g., epitaxially grown) on the growth substrate SG.

The first base semiconductor layer BSCL1 may include a material for forming a first semiconductor layer SCL1 (see FIG. 8). The base active layer BAL may include a material for forming an active layer AL (see FIG. 8). The second base semiconductor layer BSCL2 may include a material for forming a second semiconductor layer SCL2 (see FIG. 8).

The reflective electrodes RE may be provided to be coupled to the bonding electrode BO in a subsequent process. The reflective electrodes RE may be patterned in the predetermined reference shape. In an embodiment, for example, the reflective electrodes RE may be disposed to correspond to the positions of the respective light emitting elements LE which are individually divided or separated from each other.

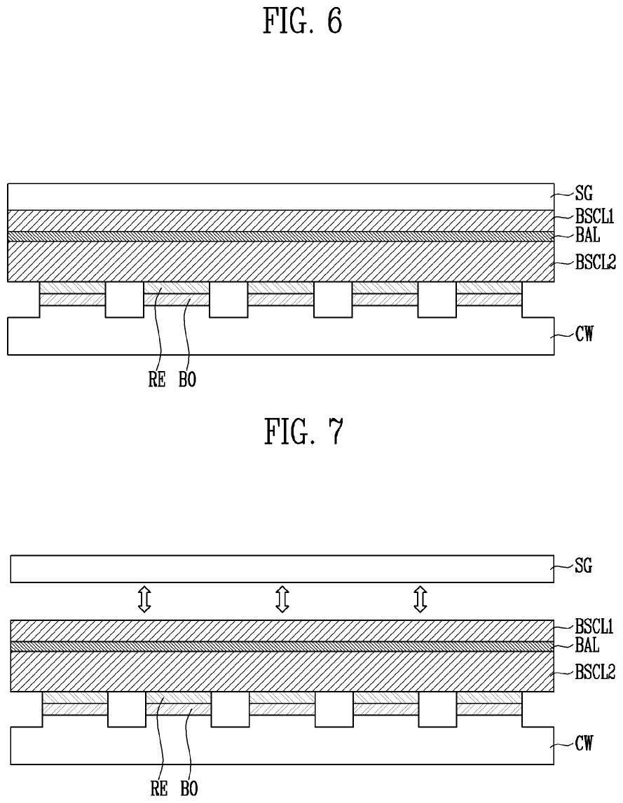

Referring to FIG. 6, in the process S100 of providing the carrier module including the carrier wafer and the light emitting element, as the reflective electrodes RE and the bonding electrodes BO are coupled to each other, the semiconductor layers BSCL1, BAL, and BSCL2 stacked on the growth substrate SG may be coupled to the carrier wafer CW.

In accordance with an embodiment, after the reflective electrodes RE are disposed on the bonding electrodes BO, the bonding electrodes BO and the reflective electrodes RE may be coupled to each other by applying heat (e.g., by radiating laser) between the bonding electrodes BO and the reflective electrodes RE. However, the disclosure is not limited thereto.

Referring to FIG. 7, in the process S100 of providing the carrier module including the carrier wafer and the light emitting element, the growth substrate SG may be separated.

In accordance with an embodiment, the growth substrate SG may be physically spaced apart from the first base semiconductor layer BSCL1. In some embodiments, a laser lift-off process or the like may be used to physically separate the growth substrate SG from the first base semiconductor layer BSCL1. However, the disclosure is not limited thereto.

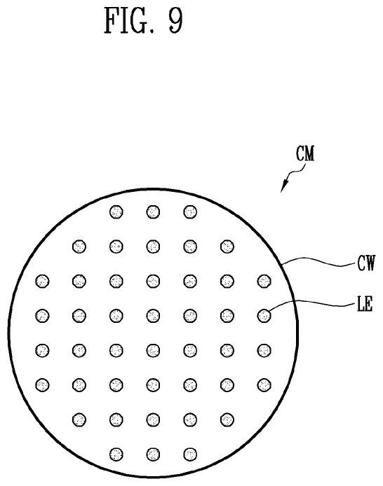

Referring to FIGS. 8 and 9, in the process S100 of providing the carrier module including the carrier wafer and the light emitting element, the semiconductor layers BSCL1, BAL, and BSCL2 may be etched, and the first semiconductor layer SCL, the active layer AL, and the second semiconductor layer SCL2, which are individually separated or spaced apart from each other, may be provided. In addition, an insulating layer INF may be patterned or provided in a pattern shape, and light emitting elements LE each including the first semiconductor layer SCL1, the active layer AL, the second semiconductor layer SCL2, and the insulating layer INF may be provided.

The first semiconductor layer SCL1 may include a semiconductor layer having a type different from a type of the second semiconductor layer SCL2. In an embodiment, for example, the first semiconductor layer SCL1 may include an N-type semiconductor. The first semiconductor layer SCL1 may include a GaN-based material. In an embodiment, for example, the first semiconductor layer SCL1 may include at least one selected from InAlGaN, GaN, AlGaN, and InGaN, and include an N-type semiconductor layer doped with a first conductivity type dopant such as Si, Ge or Sn.

The active layer AL may be disposed between the first semiconductor layer SCL1 and the second semiconductor layer SCL2. The active layer AL may include a single-quantum well structure or a multi-quantum well structure.

The active layer AL may include a well layer and a barrier layer, which collectively define a quantum well structure. In an embodiment, for example, a portion of the active layer AL, which is a well layer, may include InGaN. In an embodiment, for example, a portion of the active layer AL, which is a barrier layer, may include GaN.

The second semiconductor layer SCL2 may include a semiconductor layer having a type different from the type of the first semiconductor layer SCL1. In an embodiment, for example, the second semiconductor layer SCL2 may include a P-type semiconductor. The second semiconductor layer SCL2 may include a GaN-based material. In an embodiment, for example, the second semiconductor layer SCL2 may include at least one selected from InAlGaN, GaN, AlGaN, and InGaN, and include a P-type semiconductor layer doped with a second conductivity type dopant such as Ge, B or Mg.

The insulating layer INF may be formed (or deposited) by various methods. In an embodiment, for example, an atomic layer deposition (ALD) process, a chemical vapor deposition (CVD) process, or the like may be used to from the insulating layer INF. However, the disclosure is not necessarily limited thereto. As the formed insulating layer INF is etched, at least a portion of the second semiconductor layer SCL2 may be electrically exposed.

In accordance with an embodiment, the light emitting elements LE may be disposed on the carrier wafer CW to be spaced apart from each other when viewed on a plane.

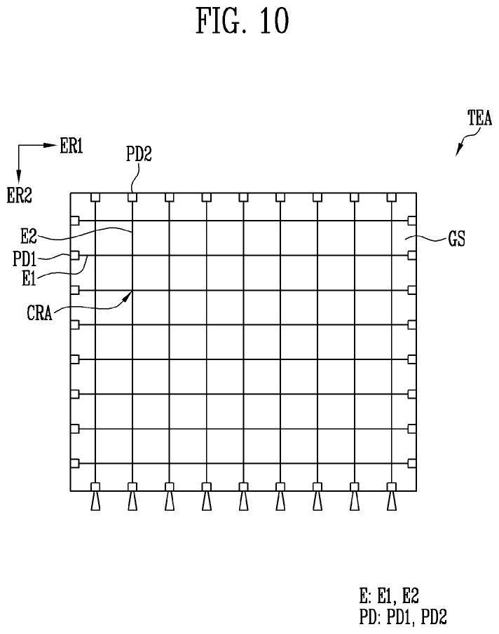

In accordance with an embodiment, positions at which the light emitting elements LE are arranged may respectively correspond to positions at which electrodes E intersect each other in a transparent electrode assembly TEA (see FIG. 10).

For example, when viewed on a plane, the light emitting elements LE may be arranged in a matrix structure defined with respect to a first arrangement direction and a second arrangement direction. In some embodiments, the light emitting elements LE may be sequentially disposed along the first arrangement direction, and be sequentially disposed along the second arrangement direction different from the first arrangement direction.

Accordingly, a carrier module CM including the light emitting elements LE and the carrier wafer CW may be provided. However, a process step for manufacturing the carrier module CM is not necessarily limited to the above-described example.

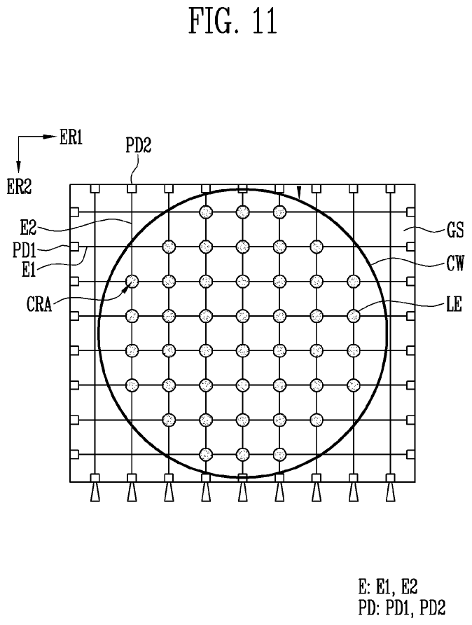

Referring to FIGS. 10 and 11, in the process S200 of disposing the carrier module on the transparent electrode assembly, the manufactured carrier module CM may be disposed on the transparent electrode assembly TEA in a way such that the positions of the light emitting elements LE respectively correspond to (or overlap) the positions at which the electrodes E intersect each other.

In accordance with an embodiment, the transparent electrode assembly TEA may be provided for an inspection process of the light emitting elements LE. The transparent electrode assembly TEA may form an area in which the carrier module CM is disposed.

The transparent electrode assembly TEA may include a glass substrate GS and electrodes E. The electrodes E may be disposed on the glass substrate GS. In an embodiment, for example, the electrodes E may be disposed directly on the glass substrate GS.

The glass substrate GS may form a base on which the electrodes E is disposed. The glass substrate GS may include a material to allow light to be transmitted therethrough. The glass substrate GS may include a glass material.

The electrodes E may include first electrodes E1 and second electrodes E2. The first electrodes E1 and the second electrodes E2 may be integrally formed with each other as a single unitary and indivisible part.

The electrodes E may have electrical conductivity, and include a transparent electrode material. The transparent electrode material may include at least one selected silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene.

The electrodes E may be electrically connected to pads PD. The pads PD may correspond to a conductive structure for supplying, to the electrodes E, an electrical signal for allowing the light emitting elements LE to emit light. In an embodiment, for example, the pads PD may include first pads PD1 and the second pads PD2. The first electrodes E1 may be electrically connected to the first pads PD1. The second electrodes E2 may be electrically connected to the second pads PD2. In some embodiments, the pads PD may be disposed in an edge area of the glass substrate GS.

The first electrodes E1 and the second electrodes E2 may extend in different directions, respectively. In an embodiment, for example, the first electrodes E1 may extend in a first extending direction ER1. The first electrodes E1 may be sequentially arranged in a second extending direction ER2. The second electrodes E2 may extend in the second extending direction ER2. The second electrodes E2 may be sequentially arranged in the first extending direction ER1.

In this process, the carrier module CM may be attached onto the transparent electrode assembly TEA, and accordingly, the transparent electrode assembly TEA may be electrically connected to at least a portion of the carrier module CM.

In some embodiments, the transparent electrode assembly TEA may be electrically connected to the carrier wafer CW. In an embodiment, for example, the transparent electrode assembly TEA may be electrically connected to the second semiconductor layer SCL2 of the light emitting element LE. In some embodiments, the light emitting elements LE may be electrically connected to the electrodes in intersection areas CRA, respectively.

The first electrodes E1 and the second electrodes E2 may intersect each other while extending in different directions. In an embodiment, for example, the first electrodes E1 and the second electrodes E2 may intersect each other in the intersection areas CRA. The intersection areas CRA may be defined at a plurality of positions. In an embodiment, for example, the intersection areas CRA may be arranged in a matrix structure. In some embodiments, the intersection areas CRA may be electrode nodes. The intersection area CRA may be arranged in a matrix form, in which a row direction is the first extending direction ER1 and a column direction is the second extending direction DR2.

In some embodiments, the structure in which the intersection areas CRA are arranged may correspond to a structure in which the light emitting elements LE are to be arranged. In an embodiment, for example, the structure (or arrangement) in which the intersection areas CRA are arranged may be substantially to the same as a structure in which the light emitting elements LE are to be arranged. Accordingly, the transparent electrode assembly TEA and the carrier module CM are coupled to each other, so that the light emitting elements LE can be respectively in the intersection areas CRA. In an embodiment, the light emitting elements LE can be arranged in a matrix form, in which a row direction is the first extending direction ER1 and a column direction is the second extending direction DR2.

Referring to FIGS. 3 and 12 to 15, in the process S300 of transferring the light emitting element, an inspection process on the light emitting elements LE disposed on the transparent electrode assembly TEA may be performed.

In the process S300 of transferring the light emitting element, it may be inspected whether the light emitting elements LE can normally emit light. In an embodiment, for example, an electrical signal for allowing light to be emitted by the light emitting elements LE may be applied to the light emitting elements LE such that the light emitting elements LE is inspected, and visual information for determining whether the light emitting elements LE normally operate may be acquired.

In accordance with an embodiment, a manufacturing apparatus (or inspecting apparatus) for performing the method of manufacturing the display device DD may include a power supply unit POW and a power apply unit PS. In accordance with an embodiment, the manufacturing apparatus (or inspecting apparatus) for performing the method of manufacturing the display device DD may include a visual inspection apparatus CAM.

In accordance with an embodiment, the power supply unit POW may supply power to the power apply unit PS. The power apply unit PS may supply an electrical signal to opposing end portions of the light emitting elements LE, and the light emitting elements LE may emit light.

In an embodiment, for example, the power apply unit PS may be electrically connected to pads PD through power supply pins PN. The power apply unit PS may supply a first electrical signal (e.g., a positive voltage or an anode signal) for allowing the light emitting elements LE to emit light to the electrodes E through the power supply pins PN and the pads PD. Accordingly, the first electrical signal for performing the inspection process may be supplied to the light emitting elements LE.

The power apply unit PS may supply a second electrical signal (e.g., a negative voltage or a cathode signal) for allowing the light emitting elements LE to emit light. In an embodiment, for example, the power apply unit PS may be electrically connected to the carrier wafer CW, and the carrier wafer CW may be electrically connected to the second semiconductor layer SCL2 through the bonding electrode BO and the reflective electrode RE. Accordingly, the second electrical signal for performing the inspection process may be supplied to the light emitting elements LE.

In this process, electrical signals applied by power apply unit PS may be applied to the first electrodes E1 and the second electrodes E2, which are arranged in a matrix structure. Accordingly, an electrical signal for performing the inspection process may be supplied to each of the light emitting elements LE.

In this process, at least some of the light emitting elements LE may emit light. In some embodiments, the light emitting elements LE provided to be normally operable may normally emit light. When some of the light emitting elements LE have an abnormal state, the some of the light emitting elements LE may not emit light.

In this process, the visual inspection apparatus CAM may acquire visual information on whether the light emitting elements LE emit light. In an embodiment, for example, the visual inspection apparatus CAM may include a camera or the like. However, the disclosure is not limited thereto.

In some embodiments, the visual information acquired by the visual inspection apparatus CAM may include mapping information of the light emitting elements LE and information on whether light is emitted for each position.

Since the positions at which the light emitting elements LE are disposed are defined to respectively correspond to the intersection areas CRA of the above-described transparent electrode assembly TEA, the mapping information representing the positions at which the light emitting elements LE are disposed may be predetermined. That light emitting elements LE emit light at specific positions can be identified based on the mapping information and the acquired visual information, and that light emitting elements LE at other positions do not emit light may be identified as a process is performed.

In an embodiment, for example, since the intersection areas CRA may be arranged in a matrix form, position information of light emitting elements LE(N) (e.g., normal light emitting elements) normally emitting light may be determined as n rows and m columns (n and m are integers of 1 or more). In addition, position information of light emitting elements LE(ABN) abnormally emitting light may be determined as x rows and y columns (x and y are integers of 1 or more).

In some embodiments, whether the light emitting elements LE normally operate may be individually determined. In some embodiments, whether the light emitting elements LE normally operate may be determined with respect to areas in which a rate at which light emitting elements LE abnormally operate is relatively high. In an embodiment, for example, areas in which the light emitting elements LE are arranged may include an abnormal area. The abnormal area may be an area in which light emitting elements LE at a predetermined rate or higher do not emit light. In some embodiments, the predetermined rate may be 80% or the like, but the disclosure is not limited thereto.

In accordance with an embodiment, the inspection process may be performed before the light emitting elements LE are transferred onto the pixel-circuit layer PCL. Experimentally, when the inspection process is performed after the light emitting elements LE are transferred, a process difficulty level may be excessively high. For example, when the inspection process is performed after the light emitting elements LE are transferred, pins for supplying an electrical signal may be respectively disposed at one end portions of the light emitting elements LE. The pins are to be electrically in contact with the end portions of the respective light emitting elements LE, but any pins may not be in contact with end portions of some light emitting elements LE. In addition, it may be difficult for a repair process of light emitting elements LE having the abnormal state to be appropriately performed, and therefore, process cost may be increased.

In accordance with an embodiment, as the transparent electrode assembly TEA is provided, the inspection process may be performed before the light emitting elements LE are transferred onto the pixel-circuit layer PCL. Accordingly, the repair process can be further optimized to be performed, and process facilities are simplified, so that the reliability of processes can be improved.

Referring to FIGS. 3 and 16, in the process S400 of repairing the light emitting element, at least some of the light emitting elements LE(ABN) (e.g., abnormal light emitting elements) determined (or identified) as being not normally operating may be repaired. Accordingly, the light emitting elements LE(ABN) which abnormally operate (e.g., determined as abnormal light emitting elements, or do not normally operate) may be repaired to be light emitting elements LE(REPAIR) which are normally operable.

In this process, a repair process may be performed on the light emitting elements LE. The repair process may be performed before the light emitting elements LE are transferred onto the pixel-circuit layer PCL such that process cost may be reduced.

In some embodiments, the some light emitting elements LE(ABN) determined to abnormally operate in the previous process may be removed, and replaced with new light emitting elements LE. Therefore, repair light emitting elements LE(REPAIR) may be provided.

In some embodiments, a process of removing the light emitting elements LE(ABN) which abnormally operate and providing the repair light emitting elements LE(REPAIR) may be performed with respect to each of the light emitting elements LE. However, the disclosure is not limited thereto. In some embodiments, the process of removing the light emitting elements LE(ABN) which abnormally operate and providing the repair light emitting elements LE(REPAIR) may be performed with respect to the areas in which the light emitting elements LE are arranged.

Referring to FIGS. 3 and 17, in the process S500 of transferring the light emitting element, the light emitting elements LE may be transferred onto the pixel-circuit layer PCL.

In this process, the carrier module CM may be separated from the transparent electrode assembly TEA. Various methods may be used as a method of separating the carrier module CM from the transparent electrode assembly TEA. In an embodiment, for example, a laser lift-off process and the like may be used to separate the carrier module CM from the transparent electrode assembly TEA, but the disclosure is not limited thereto.

In this process, as the carrier wafer CW is moved, the light emitting elements LE may be disposed on the pixel-circuit layer PCL. In some embodiments, separate electrodes may be provided on the pixel-circuit layer PCL, and the light emitting elements LE may be arranged on the electrodes. After that, although is not shown in a separate drawing, the carrier wafer CW may be removed. Accordingly, the light emitting elements LE may be electrically connected to a pixel circuit included in the pixel-circuit layer PCL to emit light.

After that, upper members such as a window may be disposed on the light emitting elements LE, and the display device DD in accordance with an embodiment of the disclosure may be provided.

In accordance with embodiments of the present disclosure, there can be provided a method of manufacturing a display device and a display device, in which a failure rate of light emitting elements is decreased, so that process efficiency can be improved.

In accordance with embodiments of the present disclosure, there can be provided a method of manufacturing a display device and a display device, in which an inspection process on a light emitting element can be appropriately performed.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of manufacturing a display device, the method comprising:
providing a carrier module including a carrier wafer and light emitting elements;
disposing the carrier module on a transparent electrode assembly;
inspecting the light emitting elements; and
transferring the light emitting elements onto a pixel-circuit layer after the inspecting the light emitting elements.

2. The method of claim 1, wherein the providing the carrier module includes:
growing semiconductor layers on a growth substrate;
providing the light emitting elements by etching the semiconductor layers, wherein the light emitting elements are spaced apart from each other, and each of the light emitting elements includes a first semiconductor layer, a second semiconductor layer, and an active layer between the first semiconductor layer and the second semiconductor layer;
coupling the light emitting elements and the carrier wafer to each other; and
separating the light emitting elements and the growth substrate from each other.

3. The method of claim 1, wherein the carrier wafer includes silicon (Si).

4. The method of claim 1, wherein the carrier wafer has electrical conductivity.

5. The method of claim 2, wherein the providing the carrier module includes:
providing a bonding electrode in a pattern shape on the carrier wafer; and
providing a reflective electrode in a pattern shape on the semiconductor layers.

6. The method of claim 1, wherein the transparent electrode assembly includes a glass substrate, and electrodes disposed on the glass substrate, and
wherein the electrodes include:
first electrodes extending in a first extending direction; and
second electrodes extending in a second extending direction different from the first extending direction, wherein the second electrodes are integrally formed with the first electrodes as a single unitary and indivisible part.

7. The method of claim 6, wherein the first electrodes and the second electrodes intersect each other in intersection areas, and
wherein the intersection areas are arranged in a matrix form in which a row direction is the first extending direction and a column direction is the second extending direction.

8. The method of claim 6, wherein the glass substrate includes a glass material, and
the electrodes include a transparent electrode material.

9. The method of claim 6, wherein the inspecting the light emitting elements includes supplying power to the electrodes such that the power is supplied to the light emitting elements.

10. The method of claim 9, wherein the supplying the power to the electrodes includes supplying, by a power apply unit, the power to pads connected to the electrodes through a power supply pin.

11. The method of claim 7, wherein the inspecting the light emitting elements includes allowing the light emitting elements to emit light.

12. The method of claim 11, wherein the inspecting the light emitting elements includes acquiring visual information on the light emitting elements, and
Wherein the visual information includes mapping information of the light emitting elements on the transparent electrode assembly and information on whether the light emitting elements emit light for each of positions at which the light emitting elements are disposed, respectively.

13. The method of claim 12, wherein the mapping information is predetermined based on the matrix form defined by the intersection areas.

14. The method of claim 12, further comprising:
repairing at least one of the light emitting elements,
wherein the repairing is performed after the inspecting the light emitting elements, and is performed before the transferring the light emitting elements onto the pixel-circuit layer.

15. The method of claim 14, wherein the inspecting the light emitting elements includes:
deciding the at least one of the light emitting elements as an abnormal light emitting element which abnormally emit light; and
deciding others of the light emitting elements as a normal light emitting element which normally emit light,
wherein the repairing the at least one of the light emitting elements includes individually repairing the at least one of the light emitting elements determined as the abnormal light emitting element.

16. The method of claim 14, wherein the inspecting the light emitting elements includes:
determining the at least one of the light emitting elements as an abnormal light emitting element which abnormally emit light; and
determining others of the light emitting elements as a normal light emitting element which normally emit light,
wherein the repairing includes repairing the at least one of the light emitting elements determined as the abnormal light emitting element with respect to an area in which the abnormal light emitting element is included at a predetermined rate or higher.

17. The method of claim 1, wherein the transferring the light emitting elements onto the pixel-circuit layer includes removing the carrier wafer in the carrier module and disposing the light emitting elements on the pixel-circuit layer.

18. A display device manufactured by the method of claim 1.

19. The display device of claim 18, wherein the pixel-circuit layer includes a pixel circuit, and the light emitting elements are electrically connected to the pixel circuit.

20. The display device of claim 19, wherein each of the light emitting elements is a micro light emitting diode.
